(19) United States
(12) Patent Application Publication
(10) Pub. No.: US 2015/0145378 A1
(43) Pub. Date: May 28, 2015

(54) QUARTZ VIBRATOR AND METHOD FOR MANUFACTURING THE SAME

(71) Applicant: SAMSUNG ELECTRO-MECHANICS CO., LTD., Gyeonggi-Do (KR)

(72) Inventor: Je Hong KYOUNG, Gyeonggi-Do (KR)

(73) Assignee: SAMSUNG ELECTRO-MECHANICS CO., LTD., Gyeonggi-Do (KR)

(21) Appl. No.: 14/209,544

(22) Filed: Mar. 13, 2014

(30) Foreign Application Priority Data
Nov. 26, 2013 (KR) 10-2013-0144663

(51) Int. Cl. H01L 41/053; H03H 9/13; H01L 41/29

(52) U.S. Cl. CPC H01L 41/0533; H01L 41/29; H03H 9/13
USPC 310/361; 310/365; 29/25.35

(57) ABSTRACT

Embodiments of the invention provide a quartz vibrator and a method for manufacturing the same. The quartz vibrator includes a quartz substrate vibrating depending on an electrical signal, first and second electrodes formed on both surfaces of the quartz substrate, and a first protective layer including an opening corresponding to a trimming region of the first electrode and formed on the first electrode.

### CROSS REFERENCE TO RELATED APPLICATION

This application claims the benefit of and priority under 35 U.S.C. §119 to Korean Patent Application No. KR 10-2013-0144663, entitled, “Quartz Vibrator and Manufacturing Method Thereof,” filed on Nov. 26, 2013, which is hereby incorporated by reference in its entirety into this application.

### BACKGROUND

1. Field of the Invention

The present invention relates to a quartz vibrator and a method for manufacturing the same.

2. Description of the Related Art

A quartz vibrator is generally used for several uses such as a frequency oscillator, a frequency regulator, a frequency converter, or the like.

The quartz vibrator uses quartz having excellent piezoelectric characteristics as a piezoelectric material, in which the quartz serves as a stable, mechanical vibration generator.

In this case, the quartz used as a piezoelectric material is artificially grown in a high pressure autoclave and is processed to have an appropriate size and shape by being cut based on its crystal axis so as to have desired characteristics, such that the quartz may be manufactured in a wafer form.

In this case, the quartz needs to be formed to have a low phase noise, a high quality (Q) value, and a low frequency change rate against a change in time and environment.

Here, the Q value indicates band selection characteristics in a resonator, a filter, an oscillator, and the like, and is called a quality factor. In addition, the Q value is calculated as a ratio of a central frequency to a 3 decibel (dB) bandwidth and the larger the Q value, the better the frequency selection characteristics of the oscillator becomes.

Such a quartz vibrator is completed by finely processing a quartz substrate three dimensionally by a micro electro mechanical system (MEMS), forming an upper electrode and a lower electrode, and mounting these electrodes in a ceramic package.

In this case, to tune a resonance frequency of the quartz vibrator to a range of an available frequency prior to completing a final package, a frequency trimming process is performed.

The frequency trimming process proceeds by etching a surface of an electrode by colliding a high energy ion beam emitted from an ion gun with an electrode.

In the process, the resonance frequency is measured in real time, a shutter of the ion gun is opened until the resonance frequency becomes the available frequency, the ion beam etches an electrode of the quartz vibrator, and the etching of the electrode ends while the shutter of the ion gun is closed when the available frequency is secured, such that the trimming process is completed.

Further, to collide the ion beam emitted from the ion gun with only the electrode of the quartz vibrator and protect the other portion from the ion beam, the frequency trimming process uses a shadow mask of which only the narrow interval is opened to meet a size of the electrode, such that the opened interval of the shadow mask, an alignment of the shadow mask the quartz vibrator, and the like, become important factors affecting the frequency trimming process.

Further, according to the prior art as described above, a frequency trimming method, which is a method of determining an electrode etching region of an ion beam through a shadow mask, cannot help increasing a trimmed area due to a tolerance of the shadow mask manufactured by mechanical processing and the alignment error of the quartz vibrator and the shadow mask.

Therefore, since it is impossible to implement the trimming at an accurate position, it is difficult to perform a precise control of a frequency, the frequency scattering is large, and in severe cases, a disconnection defect of the electrode occurs to make it difficult to manage the trimming.

### SUMMARY

Accordingly, embodiments of the present invention have been made in an effort to provide a quartz vibrator and a method for manufacturing the same capable of performing a trimming process on only a desired portion at the time of performing the trimming by forming an electrode protective layer.

According to an embodiment of the present invention, there is provided a quartz vibrator, including a quartz substrate vibrating depending on an electrical signal, first and second electrodes formed on both surfaces of the quartz substrate, and a first protective layer including an opening corresponding to a trimming region of the first electrode and formed on the first electrode.

In accordance with an embodiment of the invention, the quartz substrate is AT cut quartz substrate in which based on an X axis of an orthogonal coordinate system formed of the X axis as an electrical axis, a Y axis as a mechanical axis, and a Z axis as an optical axis which are a crystal axis of a quartz, an axis formed by leaning the Z axis in a −Y direction of the Y axis is set to be a Z′ axis and an axis formed by leaning the Y axis in a +Z axis direction of the Z axis is set to be a Y′ axis, a surface parallel with the X axis and the Z′ axis is formed, and a direction parallel with the Y′ axis is set to be a thickness.

In accordance with an embodiment of the invention, the quartz substrate includes an exciting part having a rectangular plate shape, and a peripheral part having a thickness smaller than that of the exciting part and formed around the exciting part.

In accordance with an embodiment of the invention, the quartz vibrator further includes a first pad formed at the peripheral part, and a first drawing electrode connecting the first pad to the first electrode, wherein the first protective layer is formed on the first drawing electrode.

In accordance with an embodiment of the invention, the quartz vibrator further includes a second protective layer including an opening corresponding to a trimming region of the second electrode and formed on the second electrode.

In accordance with an embodiment of the invention, the quartz vibrator further includes a second pad formed at the peripheral part, and a second drawing electrode connecting the second pad to the second electrode, wherein the second protective layer is formed on the second drawing electrode.

In accordance with an embodiment of the invention, the first protective layer includes an opening corresponding to a central portion of the first pad and may be formed on the first pad.

In accordance with an embodiment of the invention, the second protective layer includes an opening corresponding to a central portion of the second pad and may be formed on the second pad.

In accordance with an embodiment of the invention, the first protective layer is formed on a surface of the first electrode.

In accordance with an embodiment of the invention, the first protective layer is formed on the surface and a side of the first electrode.

In accordance with an embodiment of the invention, the second protective layer is formed on a surface of the second electrode.

In accordance with an embodiment of the invention, the second protective layer is formed on the surface and a side of the second electrode.

In accordance with an embodiment of the invention, the first electrode is provided with a depressed part corresponding to the opening of the first protective layer.

In accordance with an embodiment of the invention, the first protective layer is made of any one selected from a group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), and titanium oxide (TiOx).

According to another embodiment of the present invention, there is provided a method for manufacturing a quartz vibrator, including (A) forming a plurality of reserved first and second electrodes on both surfaces of a reserved quartz substrate, (B) dividing the reserved quartz substrate into the quartz substrate including one reserved first and second electrodes and formed of an exciting part and a peripheral part by using a metal mask, and (C) forming a first electrode and a second electrode formed with a first protective layer and a second protective layer after the metal mask and the reserved first and second electrodes are removed.

In accordance with an embodiment of the invention, the step (A) includes (A-1) forming a first metal layer and a second metal layer on both surfaces of a reserved quartz substrate, (A-2) forming a first resist layer on the first metal layer and forming a second resist layer on the second metal layer, (A-3) patterning the first resist layer and the second resist layer as an electrode pattern, and (A-4) forming the reserved first and second electrodes by etching the first metal layer and the second metal layer using the first resist layer and the second resist layer.

In accordance with an embodiment of the invention, the step (B) includes (B-1) forming a first metal mask on the reserved first electrode of the quartz substrate and a second metal mask on the reserved second electrode, (B-2) dividing the reserved quartz substrate into the quartz substrate including one reserved first and second electrodes by using the first and second metal masks and the first and second electrodes, and (B-3) forming the quartz substrate including the exciting part and the peripheral part by performing half etching using the first and second metal masks.

In accordance with an embodiment of the invention, the step (C) includes (C-1) removing the metal mask and the reserved first and second electrodes, (C-2) forming a third metal layer on both surfaces of the quartz substrate, (C-3) forming the first electrode on one surface of the quartz substrate and the second electrode on the other surface thereof by patterning the third metal layer, and (C-4) forming a first protective layer including an opening corresponding to a trimming region in the first electrode and a second protective layer including an opening corresponding to a trimming region in the second electrode.

In accordance with an embodiment of the invention, the step (C-4) includes forming a first insulating layer stacked on the first electrode on one surface of the quartz substrate, forming a second insulating layer stacked on the second electrode on the other surface of the quartz substrate; forming a patterned third resist layer on the first insulating layer, forming a patterned fourth resist layer on the second insulating layer, forming a first protective layer by etching the first insulating layer using the third resist layer, and forming a second protective layer by etching the second insulating layer using the fourth resist layer.

In accordance with an embodiment of the invention, the exciting part of the quartz substrate has a rectangular plate shape and the peripheral part has a thickness smaller than that of the exciting part and is formed around the exciting part.

In accordance with an embodiment of the invention, in the step (C), the first pad formed at the peripheral part and a first drawing electrode connecting the first pad to the first electrode is further formed and the first protective layer is formed on the first drawing electrode.

In accordance with an embodiment of the invention, in the step (C), the second pad formed at the peripheral part and a second drawing electrode connecting the second pad to the second electrode is further formed and the second protective layer is formed on the second drawing electrode.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a front plan view schematically illustrating a quartz vibrator, in accordance with an embodiment of the present invention.

FIG. 2 is a rear plan view schematically illustrating the quartz vibration, in accordance with an embodiment of the present invention.

FIG. 3 is a cross-sectional view taken along the line A-A′ of FIG. 1 schematically illustrating the quartz vibrator, in accordance with an embodiment of the present invention.

FIG. 4 is a cross-sectional view taken along the line B-B′ of FIG. 1 schematically illustrating the quartz vibrator, in accordance with an embodiment of the present invention.

FIG. 5 is a cross-sectional view schematically illustrating the quartz vibrator suffering from the trimming process, in accordance with an embodiment of the present invention.

FIG. 6 is a perspective view schematically illustrating an AT cut quartz substrate, in accordance with an embodiment of the present invention.

FIGS. 7 to 18 are cross-sectional views schematically illustrating a method for manufacturing a quartz vibrator, in accordance with an embodiment of the present invention.

### DETAILED DESCRIPTION

The present invention will now be described more fully hereinafter with reference to the accompanying drawings, which illustrate embodiments of the invention. This invention may, however, be embodied in many different forms and should not be construed as limited to the illustrated embodiments set forth herein. Rather, these embodiments are provided so that this disclosure will be thorough and complete, and will fully convey the scope of the invention to those skilled in the art. Like numbers refer to like elements throughout. Prime notation, if used, indicates similar elements in alternative embodiments.

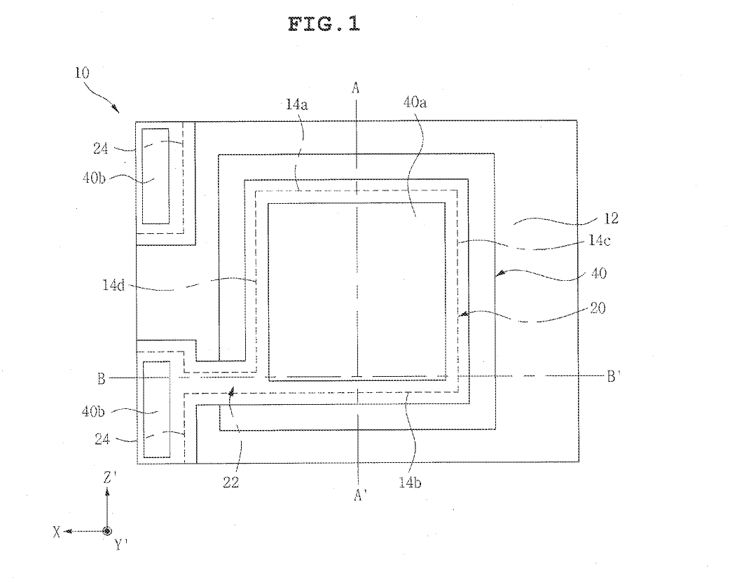

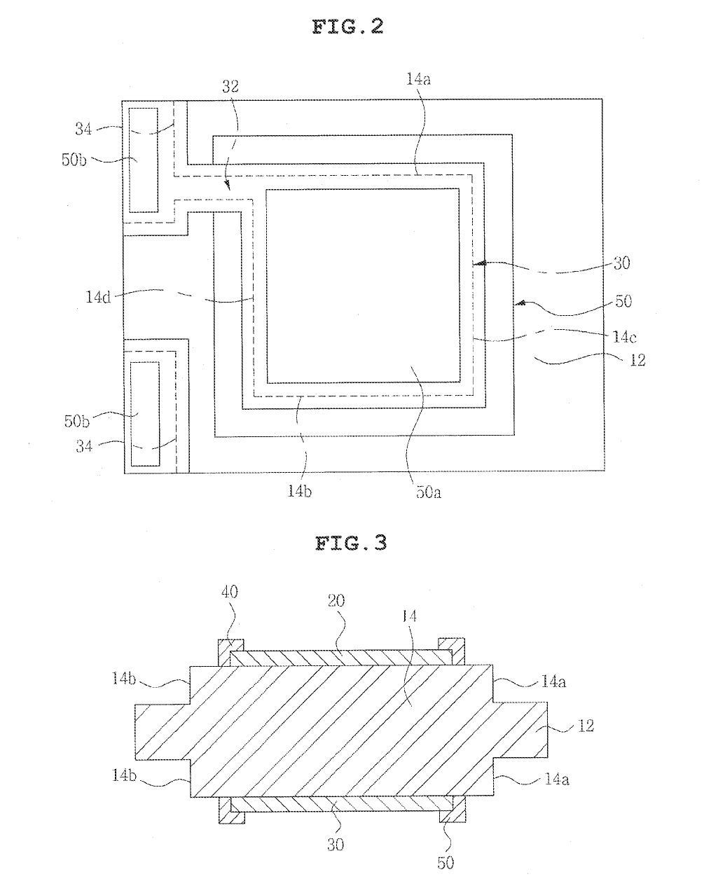

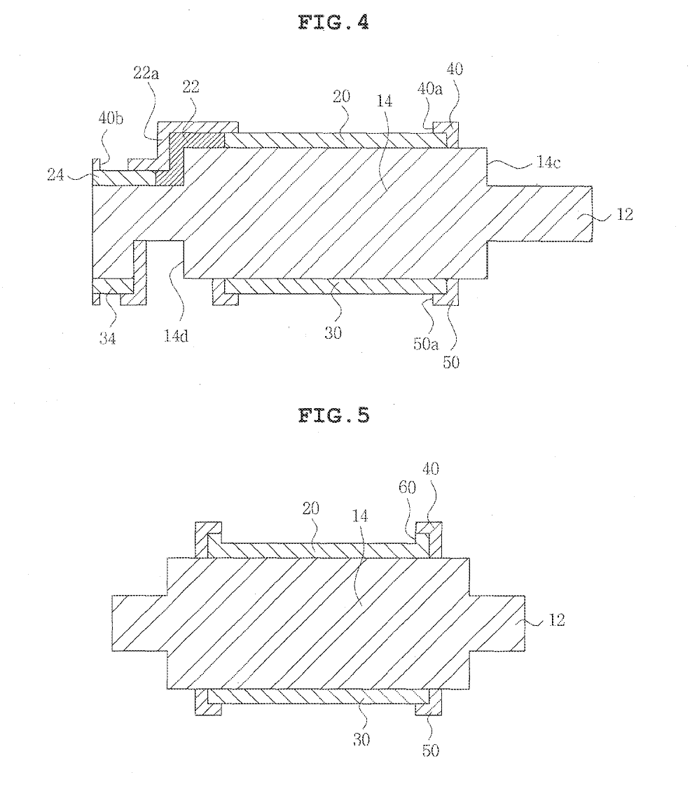

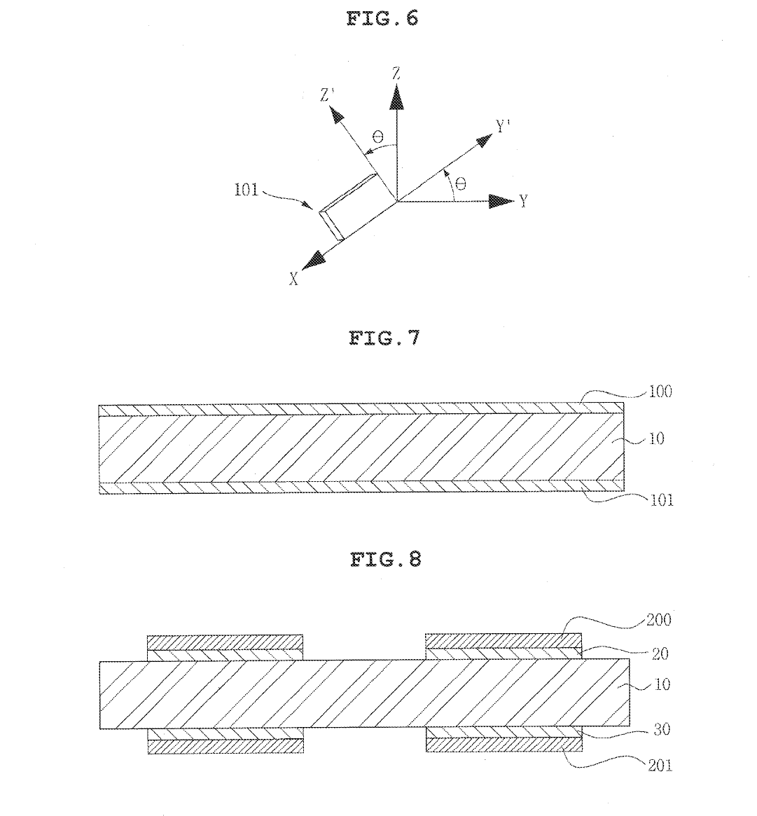

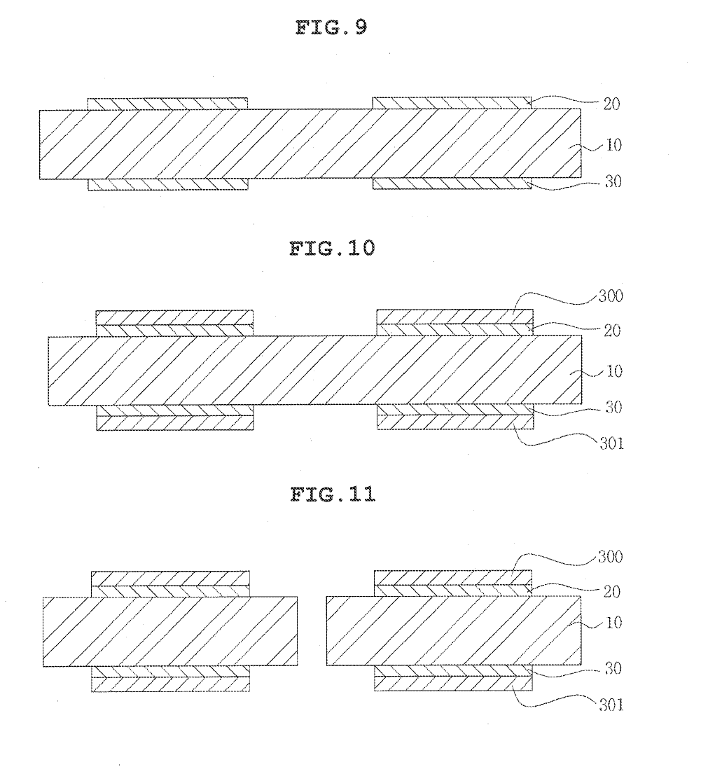

FIG. 1 is a front plan view schematically illustrating a quartz vibrator, in accordance with an embodiment of the present invention, FIG. 2 is a rear plan view schematically illustrating the quartz vibrator, in accordance with an embodiment of the present invention FIG. 3 is a cross-sectional view taken along the line A-A′ of FIG. 1 schematically illustrating the quartz vibrator, in accordance with an embodiment of the present invention, FIG. 4 is a cross-sectional view taken along the line B-B′ of FIG. 1 schematically illustrating the quartz vibrator, in accordance with an embodiment of the present invention, and FIG. 5 is a cross-sectional view schematically illustrating the quartz vibrator suffering from the trimming process, in accordance with an embodiment of the present invention.

Referring to FIGS. 1 to 4, the quartz vibrator according to a preferred embodiment of the present invention includes a quartz substrate 10, an upper electrode 20, a lower electrode 30, an upper protective layer 40, and a lower protective layer 50.

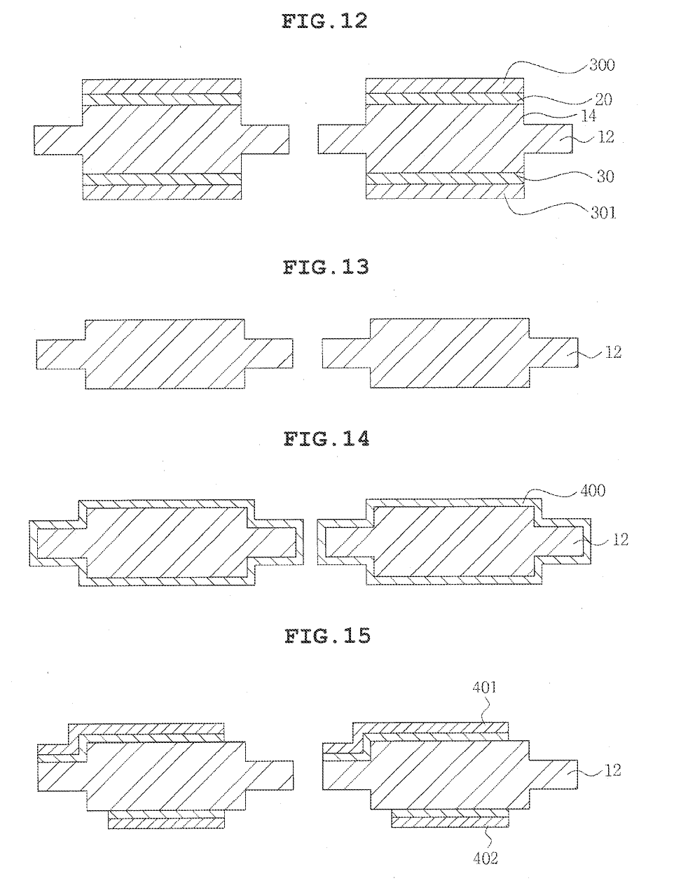

In accordance with an embodiment of the invention, the quartz substrate 10 is configured of an AT cut quartz substrate. FIG. 6 is a perspective view schematically illustrating an AT cut quartz substrate 101.

A piezoelectric material such as quartz is generally a trigonal system and has crystal axes X, Y, and Z illustrated in FIG. 5. The X axis is an electrical axis, the Y axis is a mechanical axis, and a Z axis is an optical axis.

In accordance with an embodiment of the invention, the AT cut quartz substrate 101 is a flat plate cut from a piezoelectric material (for example, synthetic quartz) along a plane at which an XZ plane rotates by the angle θ at an X-axis circumference.

Here, θ=35° 15′. Further, the Y axis and the Z axis rotates by θ at the X-axis circumference, and thus each are a Y′ axis and a Z′ axis.

Therefore, the AT cut quartz substrate 101 has crystal axes X, Y′ and Z′. The AT cut quartz substrate 101 in which an XZ′ surface (surface including the X axis and the Z′ axis) orthogonal to the Y′ axis quartz substrate is a main surface (exciting surface) may be vibrated by using a thickness shearing vibration as a main vibration. The AT cut quartz substrate 101 is processed to be able to obtain the quartz substrate 10.

In accordance with an embodiment of the invention, such a quartz substrate 10 has a rectangular shape in which as illustrated in FIGS. 1 and 2, a direction (referred to as ‘X-axis direction’) parallel with the X axis by setting a direction (hereinafter, referred to as ‘Y′-axis direction’) parallel with the Y′ axis as a thickness direction is a long side and a direction (hereinafter, referred to as ‘Z′-axis direction’) parallel with the Z′ axis is a short side. The quartz substrate 10 has a peripheral part 12 and an exciting part 14.

As illustrated in FIGS. 1 and 2, the peripheral part 12 is formed around the exciting part 14. The peripheral part 12 has a thickness smaller than that of the exciting part 14.

As illustrated in FIGS. 1 and 2, the exciting part 14 is enclosed with the peripheral part 12 and has a thickness larger than that of the peripheral part 12 in the Y′-axis direction.

That is, as illustrated in FIGS. 3 and 4, the exciting part 14 protrudes in the Y′-axis direction with respect to the peripheral part 12.

In the illustrated example, the exciting part 14 protrudes to a +Y′ side and a −Y′ side with respect to the peripheral part 12. The exciting part 14 (quartz substrate 10) has, for example, a point (not illustrated) which is a symmetrical center and, according to various embodiments, has a point symmetry shape.

As illustrated in FIGS. 1 and 2, the exciting part 14 has a rectangular shape in which the X-axis direction is a long side and the Z′-axis direction is a short side.

That is, in the exciting part 14, a side parallel with the X axis is a long side and a side parallel with the Z′ axis is a short side.

For this reason, in accordance with various embodiments, the exciting part 14 has sides 14a and 14b extending in the X-axis direction and sides 14c and 14d extending in the Z′-axis direction. That is, a length direction of the sides 14a and 14b extending in the X-axis direction is the X-axis direction and a length direction of the sides 14c and 14d extending in the Z′-axis direction is the Z′ axis direction.

In accordance with an embodiment of the invention, for example, as illustrated in FIGS. 1 and 2, the side 14a extending in the X-axis direction is formed at a +Y′ axis and −Y′ side with respect to the peripheral part 12. The same is true for the sides 14b, 14c, and 14d.

As illustrated in FIGS. 1 and 2, each of the sides 14a and 14b extending in the X-axis direction is within one plane. That is, the side 14a of the +Y′ side is within one plane and the side 14a of the −Y′ side is within one plane. Similarly, the side 14b of the +Y′ side is within one plane and the side 14b of the −Y′ side is within one plane.

Further, according to various embodiments of the invention, the ‘within one plane’ includes a case in which a side of the exciting part 14 is a flat surface and a case in which the side of the exciting part 14 has ruggedness as much as crystal anisotropy of quartz. That is, when the AT cut quartz substrate is processed by using a solution including hydrofluoric acid as an etching solution, there is the case in which the side of the exciting part 14 is a surface parallel with an XY′ surface due to the exposure of an R surface of the quartz crystal and the case in which the side of the exciting part 14 has ruggedness as much as the crystal anisotropy of quartz due to the exposure of an m surface of the quartz crystal. According to various embodiments of the invention, even the side having the ruggedness due to the m surface of the quartz crystal is believed to be the ‘within one plane’. For convenience, FIGS. 1 and 2 do not illustrate the ruggedness due to the m surface. Further, the AT cut quartz substrate is processed by a laser, such that only the R surface of the quartz crystal may be exposed.

In accordance with an embodiment of the invention, the exciting part 14 is vibrated by using the thickness shearing vibration as the main vibration.

Meanwhile, the upper electrode 20 is formed at the exciting part 14 and the lower electrode 30 is formed on a lower portion of the exciting part 14. In the example illustrated in FIGS. 3 and 4, the upper electrode 20 and the lower electrode 30 are formed, having the exciting part 14 formed therebetween.

In more detail, the upper electrode 20 and the lower electrode 30 are disposed to face each other at the front and rear of the vibration region (exciting part 14) of both main surfaces (for example, a surface parallel with the XZ′ plane) of the quartz substrate 10. The upper electrode 20 and the lower electrode 30 may apply a voltage to the exciting part 14.

In accordance with an embodiment of the invention, the upper electrode 20 is connected to the upper pad 24 formed at the peripheral part 12 through, for example, the upper drawing electrode 22. Further, the lower electrode 30 is connected to the lower pad 34 formed at the peripheral part 12 through, for example, the lower drawing electrode 32.

Herein, since a step occurs due to a difference in a thickness between the exciting part 14 and the peripheral part 12, the upper drawing electrode 22 has a step which proceeding by reflecting the step.

Further, the lower drawing electrode 32 has a step while proceeding by reflecting the step formed at the exciting part 14 and the peripheral part 12.

In accordance with an embodiment of the invention, the upper pad 24 and the lower pad 34 are formed the peripheral part 12 in a rectangular plate shape and is electrically connected to, for example, an IC chip (not illustrated) to drive a quartz vibrator 100.

The upper electrode 20, the upper drawing electrode 22, the upper pad 24, the lower electrode 30, the lower drawing electrode 32, and the lower pad 34 use, for example, a material of chromium and gold which are stacked in order from the quartz substrate 10 side.

Next, the upper protective layer 40 is formed on an upper portion and a side of the upper electrode 20 and the upper protective layer 40 includes an opening 40a formed at a central portion thereof to open a trimming region of the upper electrode 20.

Herein, the upper protective layer 40 is formed to contact the upper portion and side of the upper electrode 20, but may be formed only on the upper portion of the upper electrode 20.

Further, in accordance with an embodiment of the invention, the upper protective layer 40 may be formed on the upper portion and side of the upper drawing electrode 22 to protect the upper drawing electrode 22 so that the upper drawing electrode 22 is not etched at the time of performing the trimming process. Further, the upper protective layer 40 may be formed only on the upper portion of the upper drawing electrode 22.

Further, the upper protective layer 40 is formed to contact the upper portion and side of the upper pad 24 and protects the upper pad 24 not to etch a front surface of the upper pad 24 at the time of trimming.

In this case, the upper protective layer 40 includes an opening 40b so that an external terminal may be connected to the upper pad 24. Further, the upper protective layer 40 may be formed only on the upper portion of the upper pad 24.

Meanwhile, in accordance with an embodiment of the invention, the lower protective layer 50 is formed on a lower portion and a side of the lower electrode 30 and the lower protective layer 50 includes an opening 50a formed at a central portion thereof to open a trimming region of the lower electrode 30.

Herein, the lower protective layer 50 is formed to contact the lower portion and side of the lower electrode 30, but may be formed only on a lower portion of the lower electrode 30.

Further, in accordance with an embodiment of the invention, the lower protective layer 50 is formed on a lower portion and a side of the lower drawing electrode 32 to protect the lower drawing electrode 32, so that the lower drawing electrode 32 is not etched at the time of performing the trimming process. Further, the lower protective layer 50 is formed only on the upper portion of the lower drawing electrode 32.

Further, the lower protective layer 50 is formed to contact the lower portion and side of the lower pad 34 and protects the lower pad 34 not to etch a front surface of the lower pad 34 at the time of trimming.

In this case, the lower protective layer 50 includes an opening 50b so that the external terminal may be connected to the lower pad 34. Further, the lower protective layer 50 may be formed only on the lower portion of the lower pad 34.

In accordance with an embodiment of the invention, the upper protective layer 40 and the lower protective layer 50 are formed, having the exciting part 14 and the upper electrode 20 and the lower electrode 30 disposed therebetween.

In more detail, the upper protective layer 40 and the lower protective layer 50 are disposed to face each other at the front and rear of the vibration region (exciting part 14) of both main surfaces (for example, a surface parallel with the XZ′ plane) of the quartz substrate 10.

As such, as the upper protective layer 40 and the lower protective layer 50 are formed to be symmetrical with each other, it is possible to control the frequency by selectively etching the lower electrode 30 in addition to controlling the frequency by etching the upper electrode 20 at the time of performing the trimming process. Further, if necessary, any one of the upper protective layer 40 and the lower protective layer 50 may be omitted.

In addition, the upper protective layer 40 and the lower protective layer 50 serve to protect elements from external mechanical impact, moisture, radioactive particles, and the like.

In accordance with an embodiment of the invention, the upper protective layer 40 and the lower protective layer 50 is a nitride layer or an oxide layer. The upper protective layer 40 and the lower protective layer 50 is made of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), titanium oxide (TiOx), and the like.

According to the preferred embodiment of the present invention, the trimming process is performed by using the upper protective layer 40 or the lower protective layer 50. In the case of the final product which suffers from the trimming process, the upper electrode 20 or the lower electrode 30 which is etched has a depressed part 60 as illustrated in FIG. 6. Herein, a depth of the depressed part 60 is increased in proportion to an execution time of the trimming process and is determined depending on an available frequency and product characteristics which are required for each product.

In accordance with an embodiment of the invention, the upper protective layer 40 or the lower protective layer 50 serves as the existing shadow mask at the time of performing the trimming process to be able to radically remove the trimming region error occurring due to the mechanical processing such as the application of the existing shadow mask. Therefore, it is possible to very precisely control the trimming region.

Further, according to the preferred embodiment of the present invention, at the time of performing the frequency trimming of the quartz vibrator, only the electrode region previously patterned is trimmed, such that the frequency may be easily controlled and the frequency scattering may be kept to be small.

Further, at the time of performing the trimming by the existing method, the defect of the drawing electrode occurs due to the step between the exciting part and the peripheral part while the trimming process is performed, but by using the improved method, it is little likely to cause the defect of the drawing electrode.

Next, the method for manufacturing a quartz vibrator according to a preferred embodiment of the present invention will be described with reference to the drawings.

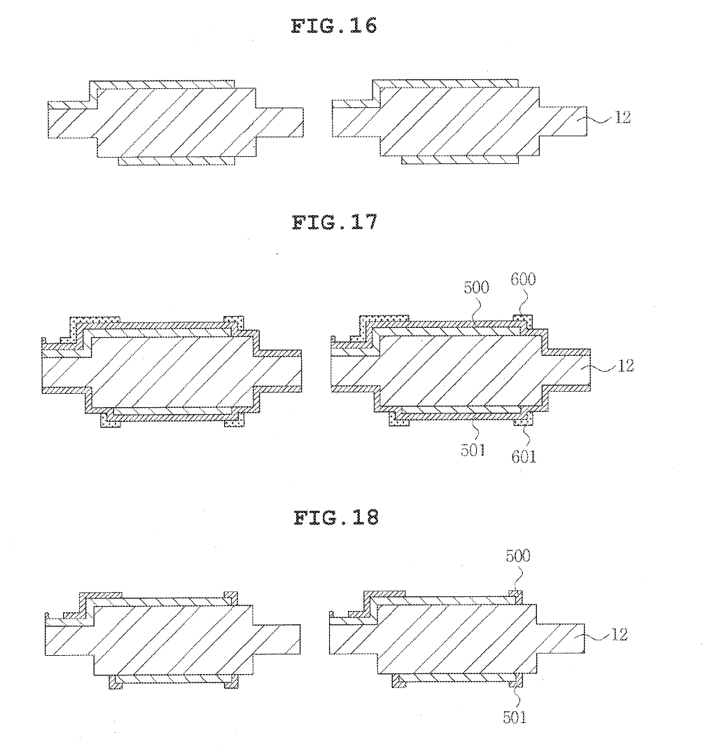

FIGS. 7 to 18 are diagrams schematically illustrating a process of manufacturing a quartz vibrator, in accordance with an embodiment of the invention.

As illustrated in FIG. 7, a front and rear main surface (surface parallel with the XZ′ plane) of the reserved quartz substrate 10 is provided with an upper metal layer 100 and the lower metal layer 101. The upper metal layer 100 and the lower metal layer 101 are formed by stacking chromium and gold in order by a spatter method, a vacuum deposition method, and the like.

In accordance with an embodiment of the invention, the upper electrode and the lower electrode are formed by patterning the upper metal layer 100 and the lower metal layer 101. To this end, the patterning is performed. The patterning is performed by, for example, the photolithography technology and the etching technology.

As illustrated in FIG. 8, a positive type photoresist layer is applied on the upper metal layer 100 and the lower metal layer 101 and is then exposed and developed to form an upper resist layer 200 and a lower resist layer 201 having a predetermined shape.

Further, according to various embodiments, the upper electrode 20 and the lower electrode 30 are reservedly formed by etching the exposed portion of the upper metal layer 100 and the lower metal layer using the so formed upper resist layer 200 and lower resist layer 201.

When the upper electrode 20 and the lower electrode 30 are reservedly formed using the upper resist layer 200 and the lower resist layer 201, as illustrated in FIG. 9, the upper resist layer 200 and the lower resist layer 201 are removed.

Next, as illustrated in FIG. 10, an upper metal mask 300 formed by stacking chromium (Cr), gold (Au), and the like, in order from the reserved quartz substrate 10 is formed on the upper electrode 20 and a lower metal mask 301 is stacked on the lower electrode 30 and then is patterned to be formed in the same shape as the exciting part 14. The patterning is performed by, for example, the photolithography technology and the etching technology.

Next, as illustrated in FIG. 11, the reserved quartz substrate 10 is etched by using the metal masks 300 and 301 and the upper electrode 20 and the lower electrode 30. The etching is performed by using, for example, the mixing solution of hydrofluoric acid and ammonium fluoride as the etching solution. By doing so, an appearance (shape when viewed in the Y′-axis direction) of the quartz substrate 10 on which the one reserved upper electrode 20 and lower electrode 30 are disposed is formed.

Next, as illustrated in FIG. 12, the quartz substrate 10 is half-etched up to a predetermined depth with a predetermined etching solution by using the metal masks 300 and 301. By doing so, the appearance of the exciting part 14 is formed.

Next, as illustrated in FIG. 13, the metal masks 300 and 301 and the reservedly formed upper electrode 20 and lower electrode 30 are developed and removed. Herein, the reason of removing the reservedly formed upper electrode 20 and lower electrode 30 is to integrally form the electrode, the drawing electrode, and the pad.

As illustrated in FIG. 14, the front and rear main surfaces (surface parallel with the XZ′ plane) and side of the quartz substrate 10 is formed with a metal layer 400. The metal layer 400 is formed by stacking chromium and gold in order by the spatter method, the vacuum deposition method, and the like.

In accordance with an embodiment of the invention, the upper electrode, the upper drawing electrode, the upper pad, the lower electrode, the lower drawing electrode, and the lower pad are formed by patterning the metal layer 400. To this end, the patterning is performed. The patterning is performed by, for example, the photolithography technology and the etching technology.

As illustrated in FIG. 15, an upper resist layer 401 and a lower resist layer 402 having a predetermined shape are formed by applying the positive type photoresist layer on the metal layer 400 and then exposing and developing the photoresist layer. The shape of the upper resist layer 401 needs to have a shape corresponding to the upper electrode, the upper drawing electrode, and the upper pad and the lower resist layer 402 also needs to have a shape corresponding to the lower electrode, the lower drawing electrode, and the lower pad.

Further, according to various embodiments of the invention, the upper electrode 20, the upper drawing electrode 22, and the upper pad 24 are formed by etching the exposed portion of the metal layer 400 using the so formed upper resist layer 401.

Further, according to various embodiments of the invention, the lower electrode 30, the lower drawing electrode 32, and the lower pad 34 are formed by etching the exposed portion of the metal layer 400 using the so formed lower resist layer 402.

When the upper electrode 20, the lower electrode 30, and the like are formed using the upper resist layer 401 and the lower resist layer 402, as illustrated in FIG. 16, the upper resist layer 401 and the lower resist layer 402 are removed.

Next, as illustrated in FIG. 17, an upper insulating layer 500 and a lower insulating layer 501 formed of a nitride layer or an oxide layer are formed to form the upper protective layer and the lower protective layer.

In accordance with an embodiment of the invention, the upper insulating layer 500 and the lower insulating layer 501 is made of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), titanium oxide (TiOx), and the like.

Further, according to various embodiments of the invention, the positive type photoresist layer are applied to form the upper protective layer 40 and the lower protective layer 50 by patterning the upper insulating layer 500 and the lower insulating layer 501.

Next, an upper resist layer 600 and a lower resist layer 601 having a predetermined shape are formed by exposing and developing the photoresist layer and then the upper protective layer 40 and the lower protective layer 50 illustrated in FIG. 18 are formed by patterning the upper insulating layer 500 and the lower insulating layer 501 using the formed upper resist layer 600 and lower resist layer 601.

In accordance with an embodiment of the invention, the upper protective layer 40 formed by the process is formed on the upper portion and a side of the upper electrode 20 and the upper protective layer 40 includes the opening 40a formed at a central portion thereof to open the trimming region of the upper electrode 20.

Further, the upper protective layer 40 is formed to contact the upper portion and side of the upper electrode 20, but is formed only on the upper portion of the upper electrode 20.

Further, according to various embodiments of the invention, the upper protective layer 40 is formed on the upper portion and side of the upper drawing electrode 22 to protect the upper drawing electrode 22 so that the upper drawing electrode 22 is not etched at the time of performing the trimming process. Further, the upper protective layer 40 is formed only on the upper portion of the upper drawing electrode 22.

Further, the upper protective layer 40 is formed to contact the upper portion and side of the upper pad 24 and protects the upper pad 24 not to etch a front surface of the upper pad 24 at the time of trimming.

In this case, the upper protective layer 40 includes an opening 40b so that an external terminal may be connected to the upper pad 24. Further, the upper protective layer 40 may be formed only on the upper portion of the upper pad 24.

Meanwhile, the lower protective layer 50 is formed on a lower portion and a side of the lower electrode 30 and the lower protective layer 50 includes an opening 50a formed at a central portion thereof to open a trimming region of the lower electrode 30.

Herein, the lower protective layer 50 is formed to contact the lower portion and side of the lower electrode 30, but is formed only on the lower portion of the lower electrode 30.

Further, according to various embodiments of the invention, the lower protective layer 50 is formed on a lower portion and a side of the lower drawing electrode 32 to protect the lower drawing electrode 32, so that the lower drawing electrode 32 is not etched at the time of performing the trimming process. Further, the lower protective layer 50 is formed only on the upper portion of the lower drawing electrode 32.

Further, according to various embodiments of the invention, the lower protective layer 50 is formed to contact the lower portion and side of the lower pad 34 and protects the lower pad 34 not to etch a front surface of the lower pad 34 at the time of trimming.

In this case, the lower protective layer 50 includes an opening 50b so that the external terminal may be connected to the lower pad 34. Further, the lower protective layer 50 is formed only on the upper portion of the lower pad 34.

When the upper protective layer 40 and the lower protective layer 50 are formed, the upper resist layer 600 and the lower resist layer 601 are removed.

According to the preferred embodiments of the present invention, it is possible to easily control the frequency and reduce the frequency scattering by precisely controlling the frequency trimming region of the quartz vibrator.

Further, according to the preferred embodiments of the present invention, it is possible to effectively prevent the drawing electrode located in the step region, and the like from short-circuiting during the frequency trimming.

Further, according to the preferred embodiments of the present invention, it is possible to simplify the trimming process since there is no need to use the shadow mask, and the like when the trimming process is performed.

Further, according to the preferred embodiments of the present invention, it is possible to improve the manufacturing competitiveness by improving the frequency scattering and the yield and simplifying the process.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

As used herein, terms such as “first,” “second,” “one side,” “the other side” and the like are arbitrarily assigned and are merely intended to differentiate between two or more components of an apparatus. It is to be understood that the words “first,” “second,” “one side,” and “the other side” serve no other purpose and are not part of the name or description of the component, nor do they necessarily define a relative location or position of the component. Furthermore, it is to be understood that the mere use of the term “first” and “second” does not require that there be any “third” component, although that possibility is contemplated under the scope of the embodiments of the present invention.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A quartz vibrator, comprising:
a quartz substrate vibrating depending on an electrical signal;
first and second electrodes formed on both surfaces of the quartz substrate; and
a first protective layer including an opening corresponding to a trimming region of the first electrode and formed on the first electrode.

2. The quartz vibrator as set forth in claim 1, wherein the quartz substrate is an AT cut quartz substrate in which based on an X axis of an orthogonal coordinate system formed of the X axis as an electrical axis, a Y axis as a mechanical axis, and a Z axis as an optical axis which are a crystal axis of a quartz, an axis formed by leaning the Z axis in a −Y direction of the Y axis is set to be a Z′ axis and an axis formed by leaning the Y axis in a +Z axis direction of the Z axis is set to be a Y′ axis, a surface parallel with the X axis and the Z′ axis is formed, and a direction parallel with the Y′ axis is set to be a thickness.

3. The quartz vibrator as set forth in claim 1, wherein the quartz substrate comprises:
an exciting part having a rectangular plate shape; and
a peripheral part having a thickness smaller than that of the exciting part and formed around the exciting part.

4. The quartz vibrator as set forth in claim 3, further comprising:
a first pad formed at the peripheral part; and
a first drawing electrode connecting the first pad to the first electrode,
wherein the first protective layer is formed on the first drawing electrode.

5. The quartz vibrator as set forth in claim 3, further comprising:
a second protective layer including an opening corresponding to a trimming region of the second electrode and formed on the second electrode.

6. The quartz vibrator as set forth in claim 5, further comprising:
a second pad formed at the peripheral part; and
a second drawing electrode connecting the second pad to the second electrode,
wherein the second protective layer is formed on the second drawing electrode.

7. The quartz vibrator as set forth in claim 4, wherein the first protective layer comprises an opening corresponding to a central portion of the first pad and formed on the first pad.

8. The quartz vibrator as set forth in claim 6, wherein the second protective layer comprises an opening corresponding to a central portion of the second pad and formed on the second pad.

9. The quartz vibrator as set forth in claim 1, wherein the first protective layer is formed on a surface of the first electrode.

10. The quartz vibrator as set forth in claim 1, wherein the first protective layer is formed on the surface and a side of the first electrode.

11. The quartz vibrator as set forth in claim 5, wherein the second protective layer is formed on a surface of the second electrode.

12. The quartz vibrator as set forth in claim 5, wherein the second protective layer is formed on the surface and a side of the second electrode.

13. The quartz vibrator as set forth in claim 1, wherein the first electrode is provided with a depressed part corresponding to the opening of the first protective layer.

14. The quartz vibrator as set forth in claim 1, wherein the first protective layer is made of any one selected from the group consisting of aluminum oxide (Al₂O₃), aluminum nitride (AlN), aluminum oxynitride (AlON), silicon oxide (SiOx), silicon nitride (SiNx), silicon oxynitride (SiOxNy), silicon carbide (SiC), and titanium oxide (TiOx).

15. A method for manufacturing a quartz vibrator, comprising:
(A) forming a plurality of reserved first and second electrodes on both surfaces of a reserved quartz substrate;
(B) dividing the reserved quartz substrate into the quartz substrate including one reserved first and second electrodes and formed of an exciting part and a peripheral part by using a metal mask; and
(C) forming a first electrode and a second electrode formed with a first protective layer and a second protective layer after the metal mask and the reserved first and second electrodes are removed.

16. The method as set forth in claim 15, wherein the step (A) includes:
(A-1) forming a first metal layer and a second metal layer on both surfaces of a reserved quartz substrate;
(A-2) forming a first resist layer on the first metal layer and forming a second resist layer on the second metal layer;
(A-3) patterning the first resist layer and the second resist layer as an electrode pattern; and
(A-4) forming the reserved first and second electrodes by etching the first metal layer and the second metal layer using the first resist layer and the second resist layer.

17. The method as set forth in claim 15, wherein the step (B) comprises:
(B-1) forming a first metal mask on the reserved first electrode of the quartz substrate and a second metal mask on the reserved second electrode;
(B-2) dividing the reserved quartz substrate into the quartz substrate including one reserved first and second electrodes by using the first and second metal masks and the first and second electrodes; and
(B-3) forming the quartz substrate including the exciting part and the peripheral part by performing half etching using the first and second metal masks.

18. The method as set forth in claim 15, wherein the step (C) comprises:
(C-1) removing the metal mask and the reserved first and second electrodes;
(C-2) forming a third metal layer on both surfaces of the quartz substrate;
(C-3) forming the first electrode on one surface of the quartz substrate and the second electrode on the other surface thereof by patterning the third metal layer; and
(C-4) forming a first protective layer including an opening corresponding to a trimming region in the first electrode and a second protective layer including an opening corresponding to a trimming region in the second electrode.

19. The method as set forth in claim 18, wherein the step (C-4) comprises:
forming a first insulating layer stacked on the first electrode on one surface of the quartz substrate;
forming a second insulating layer stacked on the second electrode on the other surface of the quartz substrate;
forming a patterned third resist layer on the first insulating layer;
forming a patterned fourth resist layer on the second insulating layer;
forming a first protective layer by etching the first insulating layer using the third resist layer; and
forming a second protective layer by etching the second insulating layer using the fourth resist layer.

20. The method as set forth in claim 17, wherein the exciting part of the quartz substrate has a rectangular plate shape, and the peripheral part has a thickness smaller than that of the exciting part and formed around the exciting part.

21. The method as set forth in claim 20, wherein in the step (C), the first pad formed at the peripheral part and a first drawing electrode connecting the first pad to the first electrode are further formed and the first protective layer is formed on the first drawing electrode.

22. The method as set forth in claim 20, wherein in the step (C), the second pad formed at the peripheral part and a second drawing electrode connecting the second pad to the second electrode are further formed and the second protective layer is formed on the second drawing electrode.
